(19) United States
(12) Patent Application Publication
(10) Pub. No.: US 2024/0421789 A1
(43) Pub. Date: Dec. 19, 2024

(54) Bulk Acoustic Resonator and Preparation Method Thereof and Filter

(71) Applicant: Wuhan MEMSonics Technologies Co.,Ltd., Wuhan Hubei (CN)

(72) Inventors: Zhipeng DING, Singapore (SG); Yan LIU, Wuhan Hubei (CN); Don Daw CHEAM, Singapore (SG); Chengliang SUN, Wuhan Hubei (CN)

(21) Appl. No.: 18/742,928

(22) Filed: Jun. 13, 2024

(30) Foreign Application Priority Data
Jun. 14, 2023 (CN) 202310710126.7

(51) Int. Cl. H03H 3/02; H03H 9/17

(52) U.S. Cl. CPC H03H 3/02; H03H 9/173; H03H 2003/021

(57) ABSTRACT

The present application provides a bulk acoustic resonator and a preparation method thereof, and a filter. The bulk acoustic resonator includes: a substrate, wherein the substrate includes a first semiconductor layer, an insulating layer and a second semiconductor layer, which are stacked in sequence; the surface of the second semiconductor layer is etched to form a groove, and the groove penetrates through the second semiconductor layer; and a protection part is formed in the groove, and a vertical section of the groove has a smooth contour.

### CROSS-REFERENCE TO RELATED APPLICATION

The present disclosure claims the priority of Chinese patent application no. 202310710126.7, filed with the China National Intellectual Property Administration on Jun. 14, 2023 and entitled “Bulk Acoustic Resonator and Preparation Method Thereof, and Filter”, which is incorporated herein by reference in its entirety.

### TECHNICAL FIELD

The present application relates to the technical field of filters, and in particular, to a bulk acoustic resonator and a preparation method thereof, and a filter.

### BACKGROUND

A bulk acoustic wave (BAW) filter composed of an FBAR (film bulk acoustic resonator, film bulk acoustic resonator) may meet the requirements of the current high-performance radio-frequency filter, and is a brand-new radio-frequency filter solution.

At the present stage, the FBAR mainly includes a silicon substrate with a cavity, and a “sandwich” laminated structure composed of a bottom electrode, a piezoelectric layer and a top electrode, which are sequentially stacked on the substrate. The FBAR specifically utilizes the piezoelectric characteristics of the material to convert electric energy into acoustic energy, an acoustic wave is reflected back and forth in the “sandwich” structure to form a standing wave, the frequency of the standing wave is the same as the frequency of an input signal, at this time, the electrical loss is the minimum, and the input signal with the frequency of f passes through the resonator. The main performance indicators of the FBAR include a series resonant frequency, a parallel resonant frequency, an effective electromechanical coupling coefficient (k2eff), and a quality factor (Q).

In related preparation technology of the FBAR, an amorphous oxide layer, such as SiO₂, PSG (Phospho Silicate Glass, phospho silicate glass), TEOS (ethyl silicate), and HDP (High Density Plasma, high density plasma), is usually buried in the cavity of the silicon substrate in advance to serve as a sacrificial layer; and then, a seed layer, a bottom electrode, a piezoelectric layer and a top electrode are deposited on the sacrificial layer. However, due to crystal mismatch, a high-quality bulk acoustic resonator cannot be obtained, thereby greatly reducing the performance of a BAW device.

### SUMMARY

The present application provides a bulk acoustic resonator and a preparation method thereof, and a filter.

According to an embodiment of the present application, a bulk acoustic resonator is provided, the bulk acoustic resonator includes: a substrate, wherein the substrate includes a first semiconductor layer, an insulating layer and a second semiconductor layer, which are stacked in sequence; the surface of the second semiconductor layer is etched to form a groove, and the groove penetrates through the second semiconductor layer; and a protection part is formed in the groove, and a vertical section of the groove has a smooth contour.

In some embodiments, in the longitudinal direction of the second semiconductor layer, the width of the vertical section of the groove changes from large to small.

In some embodiments, the contour of the vertical section of the groove includes a trapezoid or a rectangle.

In some embodiments, the notch of the groove has an inclined section, and a inclination angle of the inclined section is not greater than 10°.

In some embodiments, a vertical height of the inclined section is not greater than two thirds of a height of the second semiconductor layer.

According to another embodiment of the present application, a preparation method of a bulk acoustic resonator is provided, wherein the method includes:
a substrate is provided, wherein the substrate includes a first semiconductor layer, an insulating layer and a second semiconductor layer, which are stacked in sequence;
an annular groove is formed in the substrate, wherein the annular groove penetrates through the second semiconductor layer;
an oxide layer is formed on a surface of the substrate, and the annular groove is filled with the oxide layer, so as to form a protection part in the annular groove;
a bottom electrode, a piezoelectric layer and a top electrode are sequentially formed on one side surface of the second semiconductor layer that faces away from the insulating layer; and
the second semiconductor layer located in the protection part is released, so as to form a cavity.

In some embodiments, a vertical section of the annular groove is rectangular; and the step: the oxide layer is formed on the surface of the substrate, and the annular groove is filled with the oxide layer, so as to form the protection part in the annular groove, includes:
an oxidation treatment is performed on the surface of the second semiconductor layer, so that a portion of the second semiconductor layer is converted into a first oxide layer;
the first oxide layer is removed, so that the width of the vertical section of the annular groove changes from large to small in the longitudinal direction of the second semiconductor layer;
a second oxide layer is formed on one side surface of the second semiconductor layer that faces away from the first semiconductor layer, and the annular groove is filled with the second oxide layer; and
the second oxide layer is removed from the side surface of the second semiconductor layer that faces away from the first semiconductor layer, and the second oxide layer in the annular groove is retained, so as to form the protection part.

In some embodiments, in the longitudinal direction of the second semiconductor layer, the width of the vertical section of the annular groove changes from large to small; and
the step: the oxide layer is formed on the surface of the substrate, and the annular groove is filled with the oxide layer, so as to form the protection part in the annular groove, includes:
a third oxide layer is formed on one side surface of the second semiconductor layer that faces away from the first semiconductor layer, and the annular groove is filled with the third oxide layer; and
the third oxide layer is removed from the side surface of the second semiconductor layer that faces away from the first semiconductor layer, and the third oxide layer in the annular groove is retained, so as to form the protection part.

In some embodiments, the vertical section of the annular groove is rectangular or tends to be rectangular; and
the step: the oxide layer is formed on the surface of the substrate, and the annular groove is filled with the oxide layer, so as to form the protection part in the annular groove, includes:
a fourth oxide layer is formed on one side surface of the second semiconductor layer that faces away from the first semiconductor layer, and the fourth oxide layer is bombarded for the first time, so as to remove the fourth oxide layer located at the notch of the annular groove, wherein the fourth oxide layer fills a portion of the annular groove;
a fifth oxide layer is formed on one side surface of the fourth oxide layer that faces away from the substrate, and the fifth oxide layer is bombarded for the second time, so as to remove the fifth oxide layer located at the notch of the annular groove, wherein the fifth oxide layer fills a portion of the annular groove; and by means of analogy in sequence, until the oxide layer completely fills the annular groove, so as to form the protection part.

According to another embodiment of the present application, a filter is provided, wherein the filter includes the bulk acoustic resonator as described above.

### BRIEF DESCRIPTION OF THE DRAWINGS

FIG. 1 is a schematic structural diagram of a bulk acoustic resonator provided in an embodiment of the present application;

FIG. 2 is a schematic structural diagram of a substrate provided in an embodiment of the present application;

FIG. 3 is a flowchart of a preparation method of a bulk acoustic resonator provided in an embodiment of the present application;

FIG. 4 to FIG. 17b are schematic structural diagrams corresponding to specific processes of the preparation method of the bulk acoustic resonator shown in FIG. 3;

FIG. 18a is another schematic structural diagram of forming an annular groove on the substrate shown in FIG. 4;

FIG. 18b is a schematic structural diagram of forming a third oxide layer 6 on the structure shown in FIG. 18a;

FIG. 19 to FIG. 29 are schematic structural diagrams corresponding to specific processes of a preparation method of a bulk acoustic resonator provided in another embodiment of the present application;

FIG. 30 is a schematic structural diagram of another bulk acoustic resonator provided in an embodiment of the present application; and

FIG. 31 is a schematic structural diagram of a filter provided in an embodiment of the present application.

### DESCRIPTION OF REFERENCE SIGNS

10—bulk acoustic resonator; 1—substrate; 11—protection part; 12—first semiconductor layer; 13—insulating layer; 14—second semiconductor layer; 141—annular groove; 15—cavity; 16—first oxide layer; 161—protrusion; 162—void; 17—second oxide layer; 18—groove; 2/2′—seed layer; 3—bottom electrode; 4—piezoelectric layer; 41—communication hole; 5—top electrode; 51—release hole; 6—third oxide layer; 7—fourth oxide layer; 8—fifth oxide layer.

### DETAILED DESCRIPTION OF THE EMBODIMENTS

A clear and complete description of technical solutions in the embodiments of the present application will be given below, in combination with the drawings in the embodiments of the present application. Apparently, the embodiments described below are merely a part, but not all, of the embodiments of the present application. All of other embodiments, obtained by those of ordinary skill in the art based on the embodiments in the present application without any creative effort, fall into the protection scope of the present application.

The terms “first”, “second” and “third” in the present application are used for descriptive purposes only, and cannot be understood as indicating or implying relative importance or implicitly indicating the number of indicated technical features. Thus, features defined with “first”, “second” and “third” may explicitly or implicitly include at least one of the features. In the description of the present application, the meaning of “a plurality of “is at least two, for example, two, three and the like, unless specifically defined otherwise. All directional indications (e.g., upper, lower, left, right, front and back) in the embodiments of the present application are only used for explaining the relative position relationship, the motion conditions and the like between various components under a certain specific posture (as shown in the drawings), and if the specific posture changes, the directional indication also changes accordingly. In addition, the terms “including” and “having” and any variations thereof are intended to cover non-exclusive inclusions. For example, processes, methods, systems, products or devices, which contain a series of steps or units, are not limited to the listed steps or units, but may optionally further include steps or units which are not listed, or optionally further include other steps or units which are inherent to these processes, methods, products or devices.

Reference herein to “embodiment” means that a particular feature, structure or characteristic described in combination with the embodiment may be contained in at least one embodiment of the present application. The appearances of the phrase at various positions in the specification are not necessarily all referring to the same embodiment, and are not independent or alternative embodiments which are mutually exclusive to other embodiments. Those skilled in the art explicitly and implicitly understand that, the embodiments described herein may be combined with other embodiments.

In the related art of preparing an FBAR, an amorphous oxide layer is usually buried in the cavity of a silicon substrate in advance to serve as a sacrificial layer; and then, a seed layer, a bottom electrode, a piezoelectric layer and a top electrode are deposited on the sacrificial layer. However, since the amorphous oxide layer is mismatched with the seed layer, the bottom electrode, the piezoelectric layer and the top electrode crystal, a high-quality bulk acoustic resonator cannot be obtained, thereby greatly reducing the performance of a BAW device.

To this end, an embodiment of the present application provides a bulk acoustic resonator, in which a protection part is formed on a substrate, and then a seed layer, a bottom electrode, a piezoelectric layer and a top electrode are directly formed on the substrate, so as to form a high-quality seed layer, a high-quality bottom electrode, a high-quality piezoelectric layer and a high-quality top electrode, thereby effectively improving the device performance of the bulk acoustic resonator.

The present application will be described in detail below with reference to the drawings and embodiments.

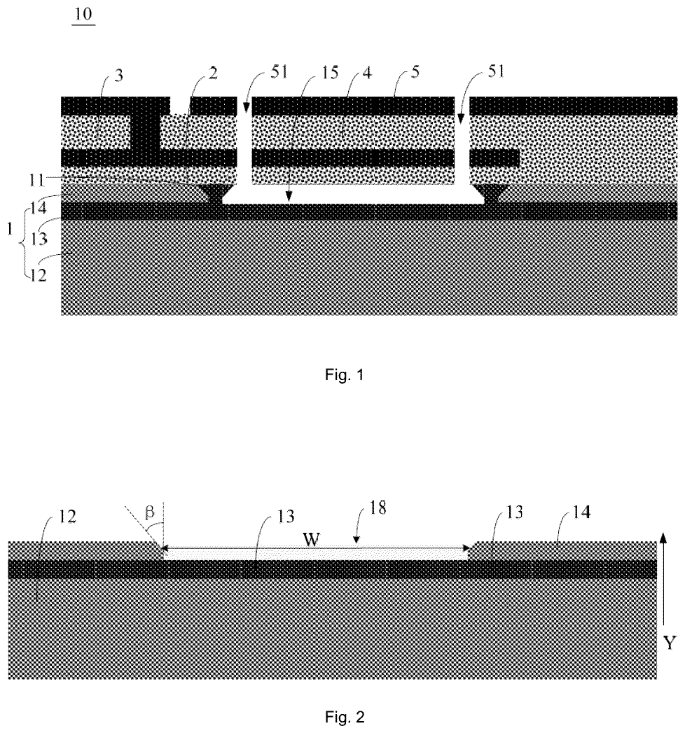

Please refer to FIG. 1 to FIG. 2, FIG. 1 is a schematic structural diagram of a bulk acoustic resonator provided in an embodiment of the present application; and FIG. 2 is a schematic structural diagram of a substrate provided in an embodiment of the present application. In the present embodiment, a bulk acoustic resonator 10 is provided. The bulk acoustic resonator 10 includes a substrate 1, a seed layer 2, a bottom electrode 3, a piezoelectric layer 4 and a top electrode 5, which are stacked in sequence.

The substrate 1 includes a first semiconductor layer 12, an insulating layer 13 and a second semiconductor layer 14, which are stacked in sequence. The first semiconductor layer 12 and/or the second semiconductor layer 14 is a silicon layer, or a germanium layer, or an SOI (Semiconductor On Insulator, semiconductor on insulator) layer, etc. The size (i.e., thickness) of the second semiconductor layer 14 in a stacking direction Y of the substrate 1 is 1 um to 5 um, for example, 2 um, 3 um, 4 um, and the like. The thickness of the first semiconductor layer 12 may be selected according to more actual requirements.

In some embodiments, at least the second semiconductor layer 14 in the first semiconductor layer 12 and the second semiconductor layer 14 is a high-resistance silicon layer, for example, the second semiconductor layer 14 is a silicon layer with a resistivity not less than 5000 Ω·cm. In this way, it can be ensured that the second semiconductor layer 14 has a relatively high resistance value, and there is no need to add other insulating layers or passivation layers between the bottom electrode 3 and the second semiconductor layer 14, so that the structure is simple, and the cost is relatively low.

Specifically, as shown in FIG. 2, the surface of the second semiconductor layer 14 is etched to form a groove 18, and the groove 18 penetrates through the second semiconductor layer 14; and a protection part 11 is formed in the groove 18, a vertical section of the groove 18 has a smooth contour, and the smooth contour may eliminate void defects occurring in the process of forming the protection part 11, wherein the smooth contour refers to that a position corresponding to the notch of the groove 18 on the vertical section of the groove 18 is provided with a right-angled or approximately right-angled sharp corner; as shown in FIG. 2, the position is a smooth oblique line or an arc with a radian, and transitions to the bottom of the groove 18, that is to say, a side edge corresponding to the vertical section of the groove 18 is not a vertical straight line, but is composed of a smooth oblique line/arc and a vertical straight line, or an inclined section of the groove 18 has a microscopic protruding structure.

Due to the presence of the rectangular groove, an oxide layer has an aggregation effect at the sharp corner of the groove during the growth process of the oxide layer, resulting in defects such as voids, steps and cracks of the oxide layer at last, thereby affecting the overall performance of the resonator; and moreover, the inventor of the present application finds that the prior art cannot solve the aggregation effect at the sharp corner of the groove. To this end, the inventor of the present application creatively proposes that the cross section of the groove 18 is designed to be inclined, the sharp corner of the groove 18 is eliminated by means of changing the contour line of the groove 18, thereby avoiding the aggregation effect caused by the sharp corner in the formation process of the oxide layer, and thus avoiding the problems of poor quality of a grown film and a decrease in the Q value of the resonator resulting from the defects of voids, steps, cracks and the like in the cavity 15; and meanwhile, it is also possible to avoid the problem that the protection part 11 loses the protection effect due to the defects, resulting in over-release of the second semiconductor layer 14, such that the bulk acoustic resonator 10 collapses and deforms, and finally the device loses efficacy.

With continued reference to FIG. 2, in the longitudinal direction Y of the second semiconductor layer 14, the width W of the vertical section of the groove 18 changes from large to small, wherein the change from large to small may be a linear change, and may also be a curved change. Of course, in the longitudinal direction Y of the second semiconductor layer 14, the width W of the vertical section of the groove 18 may also be that a portion close to the notch of the groove 18 changes from large to small, and the other portions keep the width W unchanged.

In one embodiment, the contour of the vertical section of the groove 18 includes a trapezoid or a rectangle.

Specifically, the notch of the groove 18 has an inclined section, and the inclination angle β of the inclined section is not greater than 10°. The vertical height of the inclined section is not greater than two thirds of the height of the second semiconductor layer 14, wherein the height refers to a size in the longitudinal direction Y.

The insulating layer 13 is stacked on the first semiconductor layer 12, and the second semiconductor layer 14 is stacked on one side surface of the insulating layer 13 that faces away from the first semiconductor layer 12. That is, the insulating layer 13 is located between the first semiconductor layer 12 and the second semiconductor layer 14. In this way, during the process of releasing the second semiconductor layer 14 to form the cavity 15, the insulating layer 13 may block an etching process from continuing to etch downwards in the stacking direction Y of the substrate 1, so as to limit the depth of the cavity 15 in the stacking direction Y. Since a semiconductor layer (i.e., the second semiconductor layer 14) is further disposed on the insulating layer 13, during the process of forming the bottom electrode 3 and a subsequent functional layer, the bottom electrode 3, the piezoelectric layer 4 and the top electrode 5 may be directly formed on the second semiconductor layer 14, and compared with the solution of forming the bottom electrode 3, the piezoelectric layer 4 and the top electrode 5 on the oxide layer, a high-quality seed layer 2, a high-quality bottom electrode 3, a high-quality piezoelectric layer 4 and a high-quality top electrode 5 may be formed, thereby effectively improving the device performance of the bulk acoustic resonator 10.

The material of the insulating layer 13 includes an insulating oxide. In some embodiments, the insulating oxide includes one or more of silicon oxide, silicon nitride, aluminum nitride, aluminum oxide, phospho silicate glass, ethyl silicate, thermal oxide, high density plasma (HDP), and metallic aluminum. Specifically, the insulating layer 13 is an insulating oxide layer.

The size (i.e., thickness) of the insulating layer 13 in the stacking direction Y of the substrate 1 is 0.5 um to 3 um, for example, 0.7 um, 1.2 um, 1.7 um, 2.3 um, and the like.

The protection part 11 is disposed on one side surface of the insulating layer 13 that faces away from the first semiconductor layer 12 and is in a closed loop shape, and the protection part 11 cooperates with the insulating layer 13 to form a cavity 15. The protection part 11 is used for preventing the over-release of the second semiconductor layer 14 in a transverse direction X during the process of releasing the second semiconductor layer 14 to form the cavity 15, that is, the second semiconductor layer 14 on the outer side of the protection part 11 may be blocked from being released, so as to limit the size of the cavity 15 in the transverse direction X, that is, the aperture of the cavity 15.

The cavity 15 may reflect the acoustic energy in the thickness direction of the bulk acoustic resonator 10 back into the bottom electrode 3 and the piezoelectric layer 4. Since the function of the cavity 15 is well known in the art, no repeated description is given in the present application. In the present embodiment, the cavity 15 is specifically obtained by releasing the second semiconductor layer 14. The second semiconductor layer 14 is specifically enclosed on the periphery of the protection part 11, that is, the second semiconductor layer 14 is located on one side of the protection part 11 that faces away from the cavity 15.

As described above, the cavity 15 is specifically obtained by releasing the second semiconductor layer 14, and during the process of forming the bottom electrode 3, the piezoelectric layer 4 and the top electrode 5, the bottom electrode 3, the piezoelectric layer 4 and the top electrode 5 may be directly formed on the second semiconductor layer 14, therefore compared with the solution of forming the bottom electrode 3, the piezoelectric layer 4 and the top electrode 5 on an amorphous oxide layer such as SiO₂, PSG (Phospho Silicate Glass, phospho silicate glass), TEOS (Ethyl Silicate), and HDP (high density plasma, high density plasma), a high-quality seed layer 2, a high-quality bottom electrode 3, a high-quality piezoelectric layer 4 and a high-quality top electrode 5 may be formed, thereby effectively improving the quality of the bulk acoustic resonator 10.

The height of the protection part 11 in the stacking direction Y of the substrate 1 is the same as the height of the second semiconductor layer 14 in the stacking direction Y of the substrate 1. The material of the protection part 11 includes an insulating oxide. The insulating oxide includes one or more of silicon oxide, silicon nitride, aluminum nitride, aluminum oxide, phospho silicate glass, ethyl silicate, thermal oxide, high density plasma (HDP), and metallic aluminum.

In some embodiments, as shown in FIG. 1, the transverse size of one end of the protection part 11 that faces away from the insulating layer 13 is greater than the transverse size of one end of the protection part 11 that is close to the insulating layer 13, wherein the size of the protection part 11 in the transverse direction X is the thickness of a wall of the protection part 11.

In a specific embodiment, the protection part 11 has a first portion and a second portion in the stacking direction Y, the first portion is disposed on the insulating layer 13, and the cross section of the first portion in the stacking direction Y is rectangular; the second portion is disposed on one end of the first portion that faces away from the insulating layer 13, and the size of the second portion in the transverse direction X (i.e., the thickness at a corresponding position of the protection part 11) gradually decreases in a direction close to the insulating layer 13; and at a joint of the second portion and the first portion, the size of the second portion in the transverse direction X is the same as the size of the first portion in the transverse direction X.

Specifically, as shown in FIG. 1, the vertical section of the second portion may be a trapezoid, for example, an isosceles trapezoid, a right trapezoid, or other irregular trapezoids.

Of course, in other specific embodiments, the thickness of the protection part 11 may also gradually decrease in the direction close to the insulating layer 13.

The seed layer 2 is disposed on one side surface of the second semiconductor layer 14 that faces away from the insulating layer 13, and covers a cavity opening on one end of the cavity 15 that faces away from the first semiconductor layer 12. The size (i.e., thickness) of the seed layer 2 in the stacking direction Y of the substrate 1 is 10 nm to 100 nm, for example, 20 nm, 40 nm, 60 nm, 80 nm, etc.

The bottom electrode 3 is disposed on one side surface of the seed layer 2 that faces away from the substrate 1, the piezoelectric layer 4 is disposed on one side surface of the bottom electrode 3 that faces away from the seed layer 2, the top electrode 5 is disposed on one side surface of the piezoelectric layer 4 that faces away from the bottom electrode 3, and the top electrode 5 is electrically connected with the bottom electrode 3 by means of penetrating through a lead-out metal that is disposed in the piezoelectric layer 4, so as to lead out the bottom electrode 3.

The bottom electrode 3 and the top electrode 5 are both metal electrodes, and both the bottom electrode 3 and the top electrode 5 may be made of any one or a combination of a plurality of molybdenum, platinum, gold, silver, aluminum, tungsten, titanium, ruthenium, copper and chromium. The thickness of the bottom electrode 3 is 50 nm to 400 nm, for example, 80 nm, 160 nm, 240 nm, 320 nm, and the like. The thickness of the top electrode 5 is 50 nm to 400 nm, for example, 100 nm, 160 nm, 200 nm, 240 nm, 300 nm, and the like.

The piezoelectric layer 4 is made of one or a combination of a plurality of aluminum nitride, zinc oxide, lithium niobate, PZT (lead zirconate titanate piezoelectric ceramic) and barium sodium niobate. The thickness of the piezoelectric layer 4 may be 100 nm to 2 um, for example, 300 nm, 600 nm, 900 nm, 1200 nm, 1500 nm, 1800 nm, etc.

In a specific embodiment, as shown in FIG. 1, the bulk acoustic resonator 10 is further provided with a release hole 51, and the release hole 51 extends from one side surface of the top electrode 5 that faces away from the substrate 1 to one side surface of the seed layer 2 that faces away from the bottom electrode 3, and communicates with the cavity 15 for releasing the second semiconductor layer 14 in the cavity 15 during the process of forming the cavity 15.

The bulk acoustic resonator 10 provided in the present embodiment includes the substrate 1, the bottom electrode 3, the piezoelectric layer 4 and the top electrode 5, which are stacked in sequence; the substrate 1 includes the first semiconductor layer 12, the insulating layer 13 and the second semiconductor layer 14, which are stacked in sequence; the surface of the second semiconductor layer 14 is etched to form the groove 18, and the groove 18 penetrates through the second semiconductor layer 14; and the protection part 11 is formed in the groove 18, and the vertical section of the groove 18 has the smooth contour. Due to the presence of the rectangular groove, the oxide layer has an aggregation effect at the sharp corner of the groove during the growth process of the oxide layer, resulting in defects such as voids, steps and cracks of the oxide layer at last, thereby affecting the overall performance of the resonator; and moreover, the inventor of the present application finds that the prior art cannot solve the aggregation effect at the sharp corner of the groove. To this end, the inventor of the present application creatively proposes that the cross section of the groove 18 is designed to be inclined, the sharp corner of the groove 18 is eliminated by means of changing the contour line of the groove 18, thereby avoiding the aggregation effect caused by the sharp corner in the formation process of the oxide layer, and thus avoiding the problems of poor quality of a grown film and a decrease in the Q value of the resonator resulting from the defects of voids, steps, cracks and the like in the cavity 15; and meanwhile, it is also possible to avoid the problem that the protection part 11 loses the protection effect due to the defects, resulting in over-release of the second semiconductor layer 14, such that the bulk acoustic resonator 10 collapses and deforms, and finally the device loses efficacy. Meanwhile, since the bulk acoustic resonator is provided with the protection part 11, during the process of forming the bottom electrode 3, the piezoelectric layer 4 and the top electrode 5, the bottom electrode 3, the piezoelectric layer 4 and the top electrode 5 can be directly formed on the second semiconductor layer 14, therefore compared with the solution of forming the bottom electrode 3, the piezoelectric layer 4 and the top electrode 5 on the oxide layer, a high-quality seed layer 2, a high-quality bottom electrode 3, a high-quality piezoelectric layer 4 and a high-quality top electrode 5 may be formed, thereby effectively improving the quality of the bulk acoustic resonator 10.

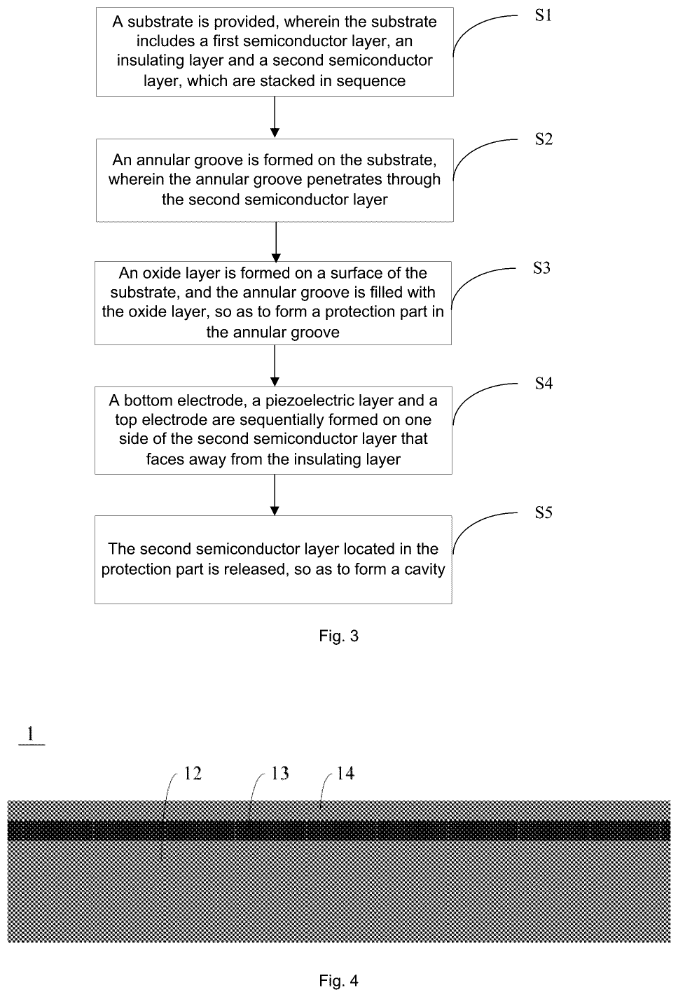

Referring to FIG. 3 to FIG. 10, FIG. 3 is a flowchart of a preparation method of a bulk acoustic resonator provided in an embodiment of the present application; and FIG. 4 to FIG. 17b are schematic structural diagrams corresponding to specific processes of the preparation method of the bulk acoustic resonator shown in FIG. 3. In the present embodiment, a preparation method of a bulk acoustic resonator is provided, and the method may be used for preparing the bulk acoustic resonator 10 provided in the above embodiment. The method includes:

Step S1: a substrate is provided, wherein the substrate includes a first semiconductor layer, an insulating layer and a second semiconductor layer, which are stacked in sequence.

As shown in FIG. 4, FIG. 4 is a diagram of a vertical section of the substrate provided in an embodiment of the present application; and the edges of the first semiconductor layer 12, the insulating layer 13 and the second semiconductor layer 14 are flush with each other. The first semiconductor layer 12 and/or the second semiconductor layer 14 is a silicon layer, or a germanium layer, or an SOI (Semiconductor On Insulator, semiconductor on insulator) layer, etc. The thickness of the second semiconductor layer 14 is 1 um to 5 um, for example, 2 um, 3 um, 4 um, and the like. The thickness of the first semiconductor layer 12 may be selected according to more actual requirements.

Preferably, the first semiconductor layer 12 may be a silicon layer having a crystal orientation index of 100. The second semiconductor layer 14 is a silicon layer having a crystal orientation index of 111.

The material of the insulating layer 13 includes an insulating oxide. In some embodiments, the insulating oxide includes one or more of silicon oxide, silicon nitride, aluminum nitride, aluminum oxide, phospho silicate glass, ethyl silicate, thermal oxide, high density plasma (HDP), and metallic aluminum. Specifically, the insulating layer 13 is an insulating oxide layer.

Step S2: an annular groove is formed on the substrate, wherein the annular groove penetrates through the second semiconductor layer.

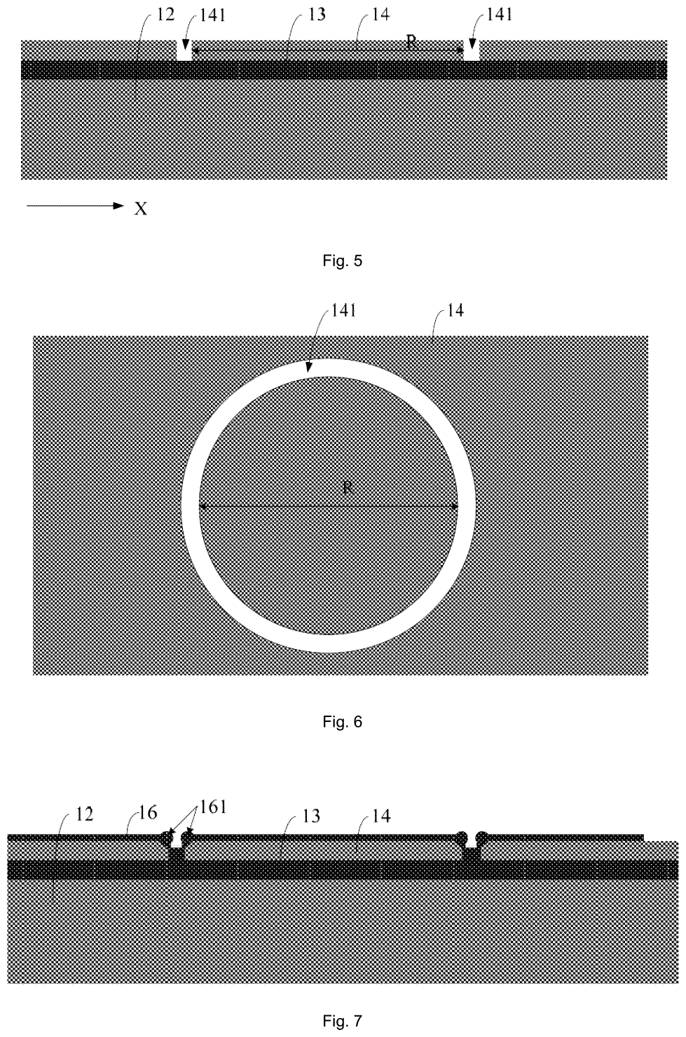

In combination with FIG. 5 and FIG. 6, FIG. 5 is a schematic structural diagram of forming the annular groove on the substrate shown in FIG. 4; and FIG. 6 is a top view corresponding to the structure shown in FIG. 5. Specifically, graphical processing may be performed on one side surface where the second semiconductor layer 14 of the substrate 1 is located, so as to form an annular groove 141; and the aperture R of a closed loop shaped pattern enclosed by the annular groove 141 is 0.5 um to 5 um, wherein if the annular groove 141 is enclosed to form a circle, the aperture R is the diameter of the circle; if the annular groove 141 is enclosed to form a square, the aperture R may be the side length of the square; and if the annular groove 141 is enclosed to form an irregular closed loop, the aperture R may be a maximum distance or a minimum distance between two points which are symmetrical about the center of the closed loop shape. In the present application, it is taken as an example that the annular groove 141 is enclosed to form a circle.

Step S3: an oxide layer is formed on a surface of the substrate, and the annular groove is filled with the oxide layer, so as to form a protection part in the annular groove.

In combination with FIG. 7 to FIG. 11, in a specific embodiment, the vertical section of the annular groove 141 is rectangular. Due to the presence of the rectangular annular groove 141, the oxide layer has an aggregation effect at the sharp corner of the groove during the growth process of the oxide layer, resulting in defects such as voids, steps and cracks of the oxide layer at last, thereby affecting the overall performance of the resonator; and moreover, the inventor of the present application finds that the prior art cannot solve the aggregation effect at the sharp corner of the groove. To this end, the inventor of the present application creatively proposes that the sharp corner of the annular groove 141 is eliminated by means of changing the contour line of the annular groove 141, thereby avoiding the aggregation effect caused by the sharp corner in the formation process of the oxide layer, and thus avoiding the problems of poor quality of a grown film and a decrease in the Q value of the resonator resulting from the defects of voids, steps, cracks and the like in the cavity 15; and meanwhile, it is also possible to avoid the problem that the protection part 11 loses the protection effect due to the defects, resulting in over-release of the second semiconductor layer 14, such that the bulk acoustic resonator 10 collapses and deforms, and finally the device loses efficacy. Specifically, in the embodiment, the step S3 specifically includes a step S31a to a step S34a.

Referring to FIG. 7, FIG. 7 is a schematic structural diagram of performing first-time oxide layer growth on the structure shown in FIG. 5 to fill the annular groove. Step S31a: an oxidation treatment is performed on the surface of the second semiconductor layer 14, so that a portion of the second semiconductor layer is converted into a first oxide layer 16, wherein the annular groove 141 is filled with the first oxide layer 16.

Specifically, the oxidation treatment may be performed on the surface of the second semiconductor layer 14 by means of processes such as thermal oxide and plasma enhanced chemical vapor deposition (PECVD). Since the second semiconductor layer 14 corresponds to the position of the annular groove 141, the oxidation treatment is performed on one side surface (hereinafter referred to as a first oxidation surface) of the second semiconductor layer 14 that faces away from the first semiconductor layer 12 and an inner wall surface (hereinafter referred to as a second oxidation surface) of the annular groove 141 at the same time, therefore, an oxidization aggregation effect occurs at an intersection position (i.e., the notch of the annular groove 141) of the first oxidation surface and the second oxidation surface, and accordingly, as shown in FIG. 7, an oxide layer protrusion 161 is formed at the intersection position, that is, a top edge of the annular groove 141.

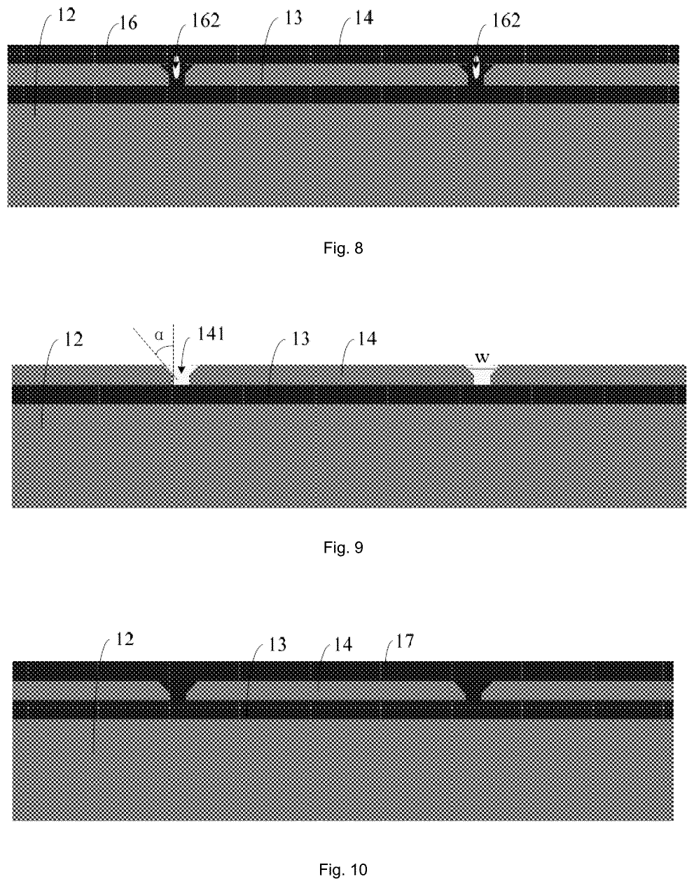

As shown in FIG. 8, FIG. 8 is a schematic structural diagram of continuing to form an oxide layer on the structure shown in FIG. 7; due to the presence of the oxide layer protrusion 161, the subsequently formed oxide layer forms voids 162, steps, cracks and other defects, and if the oxide layer having the defects such as the voids 162 is used as the protection part 11 on the substrate, the quality of the grown film becomes worse, and the Q value of the resonator is reduced; and meanwhile, the protection part 11 may lose the protection effect, and during the subsequent process of releasing the second semiconductor layer 14 in the protection part 11, the second semiconductor layer 14 outside the protection part 11 (i.e., the second semiconductor layer 14 on the both sides of the protection part 11 in FIG. 1) is also released, such that the bulk acoustic resonator 10 collapses and deforms, and finally the device loses efficacy.

Therefore, after the step S31a, as shown in FIG. 9, FIG. 9 is a schematic structural diagram of the structure shown in FIG. 8 after the first oxide layer 16 is removed. A step S32a is further included: the first oxide layer 16 is removed, so that the width w of the vertical section of the annular groove 141 changes from large to small in the longitudinal direction Y of the second semiconductor layer 14.

In the execution process of the step S32a, the sharp corner on a port edge of one end of the annular groove 141 that faces away from the insulating layer 13 is consumed, thereby becoming inclined and smooth, that is, the width w of one end of the annular groove 141 that faces away from the insulating layer 13 is greater than the width w of one end of the annular groove 141 that is close to the insulating layer 13. In this way, in the subsequent process of executing a step S33a, the whole annular groove 141 may be filled with a second oxide layer 17. In combination with FIG. 5, the width w of the annular groove 141 involved in the present application refers to a length size of the annular groove 141 in the transverse direction X. The side edge of the vertical section of the annular groove 141 may be composed of an oblique line or an arc having a radian and a straight line.

The sharp corner of the annular groove 141 is eliminated by means of changing the contour line of the annular groove 141, thereby avoiding the aggregation effect caused by the sharp corner in the subsequent formation process of the second oxide layer 17, and thus avoiding the problems of poor quality of a grown film and a decrease in the Q value of the resonator resulting from the defects of voids, steps, cracks and the like in the cavity 15; and meanwhile, it is also possible to avoid the problem that the protection part 11 loses the protection effect due to the defects, resulting in over-release of the second semiconductor layer 14, such that the bulk acoustic resonator 10 collapses and deforms, and finally the device loses efficacy.

Specifically, after being processed in the step S32a, the width w of the vertical section of the annular groove 141 changes from large to small, wherein the change from large to small may be a linear change, and may also be a curved change. Of course, in the longitudinal direction Y of the second semiconductor layer 14, the width w of the vertical section of the annular groove 141 may also be that a portion close to the notch of the annular groove 141 changes from large to small, and the other portions keep the width w unchanged.

In one embodiment, the contour of the vertical section of the annular groove 141 includes a trapezoid and a rectangle.

Specifically, the notch of the annular groove 141 has an inclined section, and the inclination angle α of the inclined section is not greater than 10°. The vertical height of the inclined section is not greater than two thirds of the height of the second semiconductor layer 14.

Referring to FIG. 10, FIG. 10 is a schematic structural diagram of forming the second oxide layer 17 on the structure shown in FIG. 9. Step S33a: the second oxide layer 17 is formed on one side surface of the second semiconductor layer 14 that faces away from the first semiconductor layer 12, and the annular groove 141 is filled with the second oxide layer 17. The second oxide layer 17 may be formed by performing second-time oxide layer growth by using a thermal oxide process.

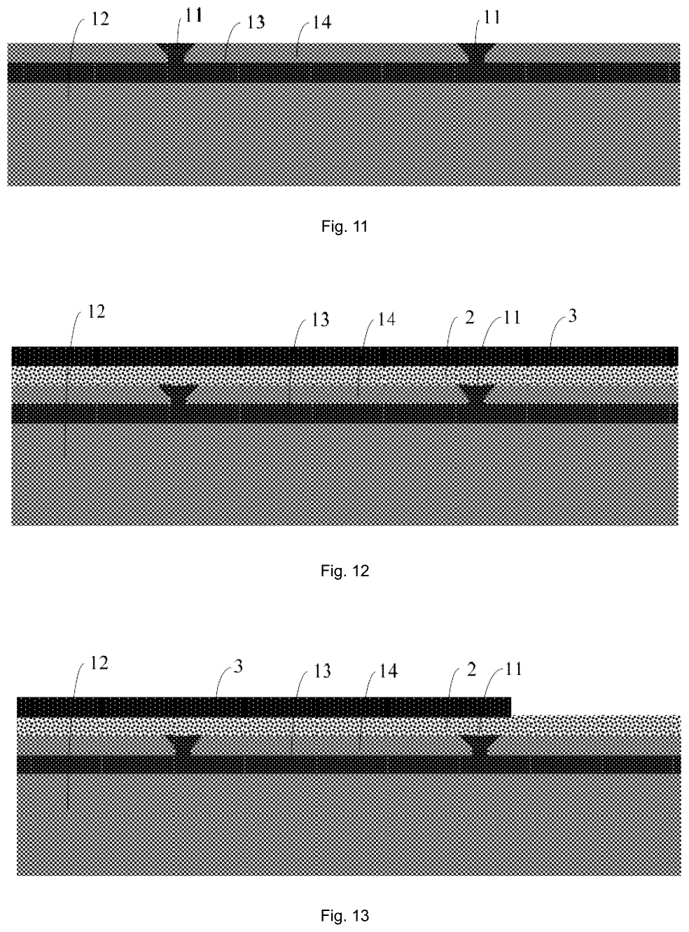

Referring to FIG. 11, FIG. 11 is a schematic structural diagram of forming the protection part 11 on the substrate 1. Step S34a: the second oxide layer 17 is removed from the side surface of the second semiconductor layer 14 that faces away from the first semiconductor layer 12, and the second oxide layer 17 in the annular groove 141 is retained, so as to form the protection part 11.

Specifically, the second oxide layer 17 may be removed from the side surface of the second semiconductor layer 14 that faces away from the first semiconductor layer 12 in a chemical-mechanical polishing (Chemical-Mechanical Polishing, CMP) manner, so as to expose the second semiconductor layer 14.

Step S4: a bottom electrode, a piezoelectric layer and a top electrode are sequentially formed on one side the second semiconductor layer that faces away from the insulating layer.

In a specific implementation process, the step S4 includes a step S41 to a step S46.

Referring to FIG. 12, FIG. 12 is a schematic structural diagram of forming a seed layer 2 and a bottom electrode 3 on the structure shown in FIG. 11. Step S41: the seed layer 2 and the bottom electrode 3 are sequentially formed on one side surface of the second semiconductor layer 14 that faces away from the insulating layer 13.

The seed layer 2 may be formed in manners such as physical vapor deposition (Physical Vapor Deposition, PVD), metal-organic chemical vapor deposition (Metal-organic Chemical Vapor DePosition, MOCVD), and atomic layer deposition (Atomic Layer Deposition, ALD). The bottom electrode 3 made be formed in a PVD manner. A temperature range of forming the seed layer 2 and the bottom electrode 3 may be 800° C. to 1500° C. The thickness of the seed layer 2 may be 10 nm to 100 nm, and the thickness of the bottom electrode 3 may be 50 nm to 400 nm.

Referring to FIG. 13, FIG. 13 is a schematic structural diagram after the graphical processing is performed on the bottom electrode 3 in the structure shown in FIG. 12. Step S42: the graphical processing is performed on the bottom electrode 3. After the graphical processing is performed on the bottom electrode 3, a portion of one side surface of the seed layer 2 that faces away from the substrate 1 is exposed via the bottom electrode 3.

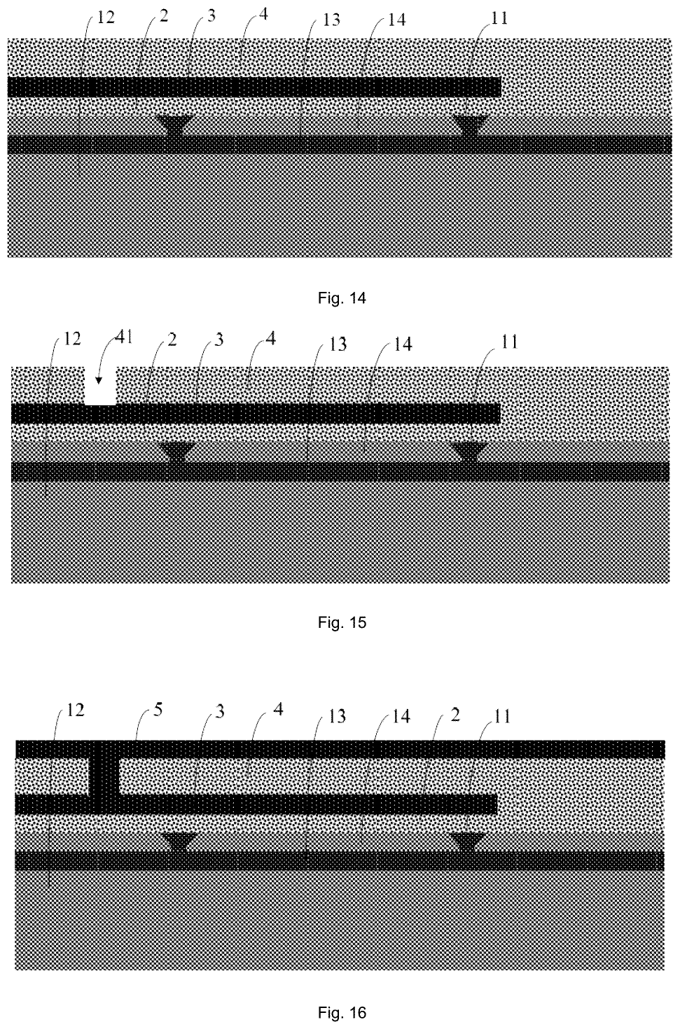

Referring to FIG. 14, FIG. 14 is a schematic structural diagram of forming a piezoelectric layer 4 on the structure shown in FIG. 13. Step S43: the piezoelectric layer 4 is formed on the side surfaces of the bottom electrode 3 and the seed layer 2 that face away from the substrate 1.

The manner of forming the piezoelectric layer 4 may be the same as or similar to the manner of forming the seed layer 2 and the bottom electrode 3. The thickness of the piezoelectric layer 4 may be 100 nm to 2 um.

Referring to FIG. 15, FIG. 15 is a schematic structural diagram of forming a communication hole in the piezoelectric layer 4. Step S44: a communication hole 41 is formed in the piezoelectric layer 4, so as to expose the bottom electrode 3, wherein communication hole 41 may be formed in the piezoelectric layer 4 by using thermalolithography or etching technology, and an orthographic projection of the communication hole 41 on the substrate 1 is located on the periphery of the protection part 11.

Referring to FIG. 16, FIG. 16 is a schematic structural diagram of forming a top electrode 5 on the structure shown in FIG. 15. Step S45: a metal material is deposited on one side surface of the piezoelectric layer 4 that faces away from the substrate 1, so as to fill the communication 41 and to form the top electrode 5, wherein the thickness of the top electrode 5 is 50 nm to 400 nm.

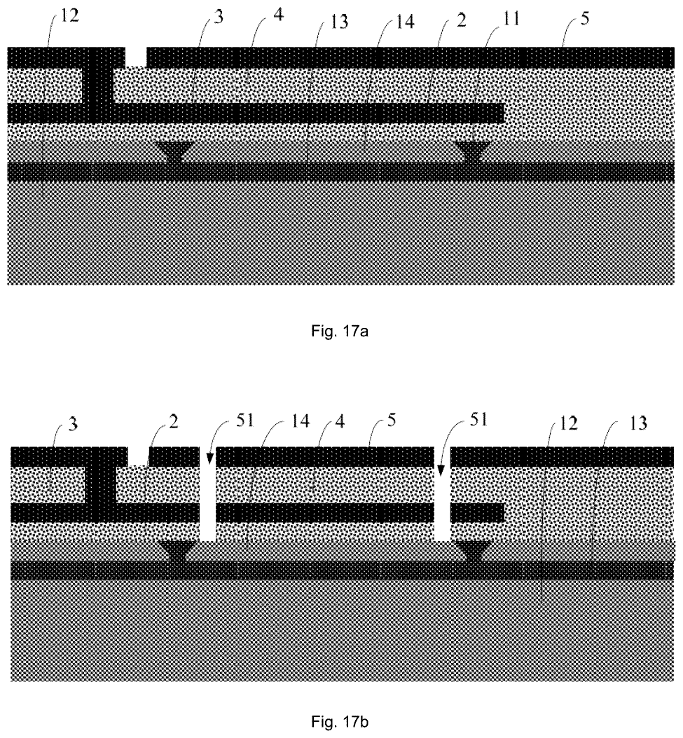

Thereafter, referring to FIG. 17a, FIG. 17a is a schematic structural diagram after the graphical processing is performed on the top electrode 5. Step S46: the graphical processing is performed on the top electrode 5.

Step S5: the second semiconductor layer located in the protection part is released, so as to form a cavity.

In some embodiments, referring to FIG. 17b, FIG. 17b is a schematic structural diagram after a release hole is formed in the structure shown in FIG. 17a. The step S5 includes:

Step S51: a release hole 51 is formed in the bottom electrode 3, the piezoelectric layer 4 and the top electrode 5. As shown in FIG. 2, the release hole 51 extends from one side surface of the top electrode 5 that faces away from the substrate 1 to a surface of the second semiconductor layer 14, and an orthographic projection of a port of the release hole 51 that faces the second semiconductor layer 14 on the substrate 1 is located in the protection part 11. Specifically, the release hole 51 extends in the stacking direction Y of the substrate 1.

Step S52: the second semiconductor layer 14 in the protection part 11 is removed by using the release hole 51, so as to form the cavity 15.

Specifically, the second semiconductor layer 14 is released by using an XeF gas, wherein since the substrate 1 is provided with the insulating layer 13 in the stacking direction Y, and is provided with the protection part 11 in the shape of a closed loop in the transverse direction X, during the process of releasing the second semiconductor layer 14, only the second semiconductor layer 14 surrounded by the protection part 11 may be released, and the second semiconductor layer 14 located on the periphery of the protection part 11 and the first semiconductor layer 12 are not released, so that the cavity 15 is formed at the position where the second semiconductor layer 14 is released, and the specific structure may refer to FIG. 2.

According to the preparation method of the bulk acoustic resonator provided in the present embodiment, the substrate 1 is provided; the substrate 1 includes the first semiconductor layer 12, the insulating layer 13 and the second semiconductor layer 14, which are stacked in sequence; then the annular groove 141 is formed in the substrate 1, and the annular groove 141 penetrates through the second semiconductor layer 14; next, the oxide layer is formed on the surface of the substrate 1, and the annular groove 141 is filled with the oxide layer, so as to form the protection part 11 in the annular groove 141; the bottom electrode 3, the piezoelectric layer 4 and the top electrode 5 are sequentially formed on the side of the second semiconductor layer 14 that faces away from the insulating layer 13; and finally, the second semiconductor layer 14 located in the protection part 11 is released, so as to form the cavity 15. In the method, the protection part 11 is provided to use the semiconductor layer as a sacrificial layer, compared with the solution of using the oxide layer as the sacrificial layer in the traditional process, a high-quality seed layer 2 and a high-quality piezoelectric layer 4 can be grown on the second semiconductor layer 14 by using the PVD and MOCVD technology, therefore method can effectively improve the quality of the prepared film bulk acoustic resonator 10 and the performance of a corresponding filter.

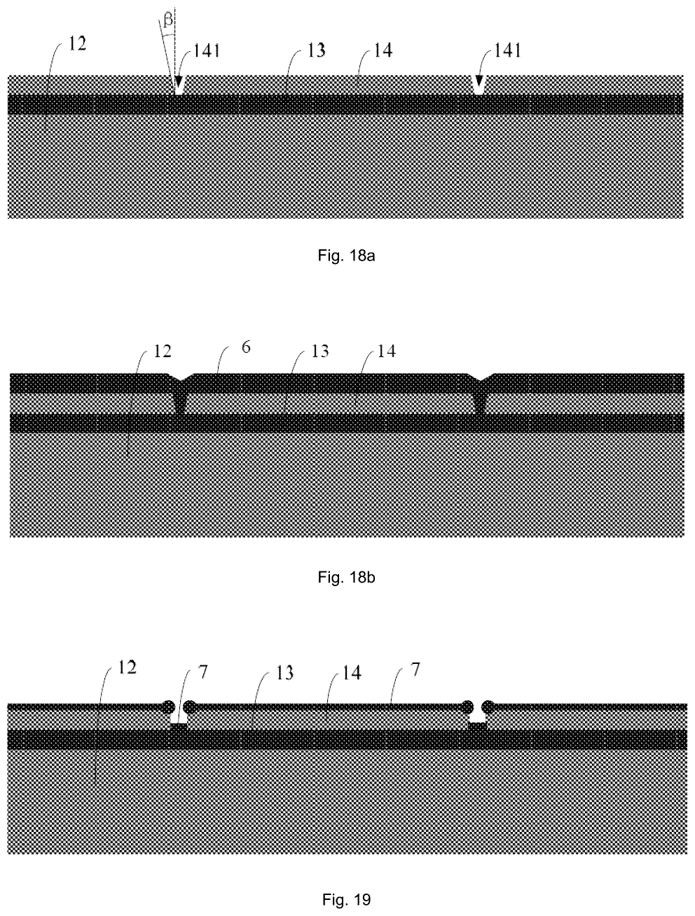

In another embodiment, another preparation method of the bulk acoustic resonator is provided, which differs from the preparation method of the bulk acoustic resonator provided in the first embodiment that: as shown in FIG. 9 or FIG. 18a, FIG. 18a is another schematic structural diagram of forming the annular groove 141 on the substrate 1 shown in FIG. 4; and regarding to the annular groove 141 formed in the step S2, in the longitudinal direction Y of the second semiconductor layer 14, the width w of the vertical section of the annular groove 141 changes from large to small. The specific structure is the same as or similar to the structure of the annular groove 141 after being processed in the step S32a. Specifically, the width w of one end of the annular groove 141 that faces away from the insulating layer 13 is greater than the width w of one end of the annular groove 141 that is close to the insulating layer 13. Specifically, the width w of the annular groove 141 may gradually decrease in the direction close to the insulating layer 13, and the vertical section of the annular groove 141 may specifically be an inverted trapezoid.

In the embodiment, the step S3 specifically includes:

As shown in FIG. 18b, FIG. 18b is a schematic structural diagram of forming a third oxide layer 6 on the structure shown in FIG. 18a. Step S31b: the third oxide layer 6 is formed on one side surface of the second semiconductor layer 14 that faces away from the first semiconductor layer 12, and the annular groove 141 is filled with the third oxide layer 6.

Specifically, an oxide layer can be grown by means of an oxide deposition process such as thermal oxide, PECVD, LPCVD and PVD, so as to form the third oxide layer 6. The thickness of the third oxide layer 6 (the size in the longitudinal direction Y) is preferably 1 um to 5 um. The material of the third oxide layer 6 may be SiO₂, PSG, TEOS, HDP, Thermal Oxide and the like, and the third oxide layer 6 needs to completely fill the annular groove 141.

Step S32b: the third oxide layer 6 is removed from the side surface of the second semiconductor layer 14 that faces away from the first semiconductor layer 12, and the third oxide layer 6 in the annular groove 141 is retained, so as to form the protection part 11.

The product structure after being processed in the step S32b is similar to that in FIG. 11.

It can be understood that, in the preparation method of the bulk acoustic resonator provided in the embodiment, the step S3 does not include the step S31b and the step S32b; and the other steps are all the same as or similar to the specific steps of the preparation method of the bulk acoustic resonator provided in the previous embodiment.

In yet another embodiment, yet another preparation method of the bulk acoustic resonator is provided, which differs from the preparation method of the bulk acoustic resonator provided in the first embodiment that: the vertical section of the annular groove 141 is rectangular (it is taken as an example in the present embodiment); or the notch of the annular groove 141 has an inclined section, and the inclination angle α of the inclined section is not greater than 5°. The step S3 includes a step S31c to a step S32c.

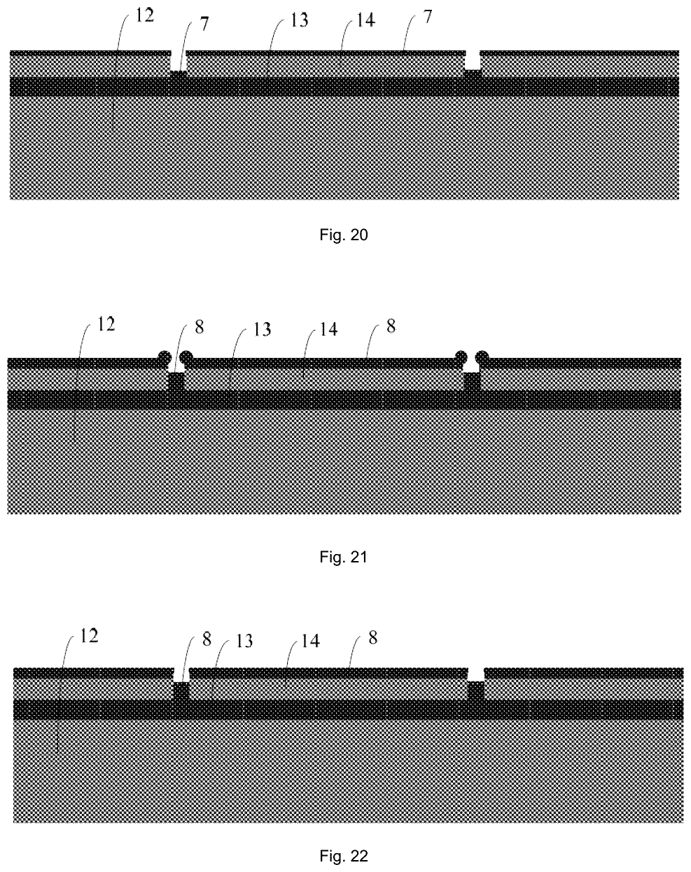

Referring to FIG. 19 to FIG. 20, FIG. 19 is a schematic structural diagram of forming a fourth oxide layer on the structure shown in FIG. 5; and FIG. 20 is a schematic structural diagram after the structure shown in FIG. 19 is bombarded. Step S31c: a fourth oxide layer 7 is formed on one side surface of the second semiconductor layer 14 that faces away from the first semiconductor layer 12, and the fourth oxide layer 7 is bombarded for the first time, so as to remove the fourth oxide layer 7 located at the notch of the annular groove 141, wherein the fourth oxide layer 7 fills a portion of the annular groove 141.

Specifically, an oxide layer may be grown by using an oxide deposition process such as PECVD, LPCVD and PVD, so as to form the fourth oxide layer 7. The thickness of the fourth oxide layer 7 may be 10 nm to 100 nm, for example, 20 nm, 40 nm, 60 nm, 80 nm, etc. Since the vertical section of the edge at the notch of the annular groove 141 is a right angle or an approximate right angle, as shown in FIG. 19, during the process of forming the fourth oxide layer 7, the fourth oxide layer 7 forms a protrusion at the notch of the annular groove 141; and due to the presence of the protrusion, a hollow protection part 11 (which is equivalent to the void 162 as mentioned above) may be formed easily; and in view of this, the protrusion is bombarded once an oxide layer is formed, so as to remove the protrusion. Then, the other oxide layers continue to be formed until the protection part 11 is formed.

After each oxide layer is formed, the protruding oxide layer is removed in a bombardment manner, and compared with other manners of removing the protrusion, there is no need to remove the product from the current chamber where the oxide layer is formed to other chambers, so as to perform a bombardment operation, that is, the bombardment operation may be directly performed in the current oxidation chamber, such that the process is simple, and the product preparation efficiency is relatively high.

Referring to FIG. 21 to FIG. 22, FIG. 21 is a schematic structural diagram of forming a fifth oxide layer 8 on the structure shown in FIG. 20; and FIG. 22 is a schematic structural diagram after the structure shown in FIG. 21 is bombarded. Step S32c: the fifth oxide layer 8 is formed on one side surface of the fourth oxide layer 7 that faces away from the substrate 1, and the fifth oxide layer 8 is bombarded for the second time, so as to remove the fifth oxide layer 8 located at the notch of the annular groove 141, wherein the fifth oxide layer 8 fills a portion of the annular groove 141; and by means of analogy in sequence, until the oxide layer completely fills the annular groove 141, so as to form the protection part 11.

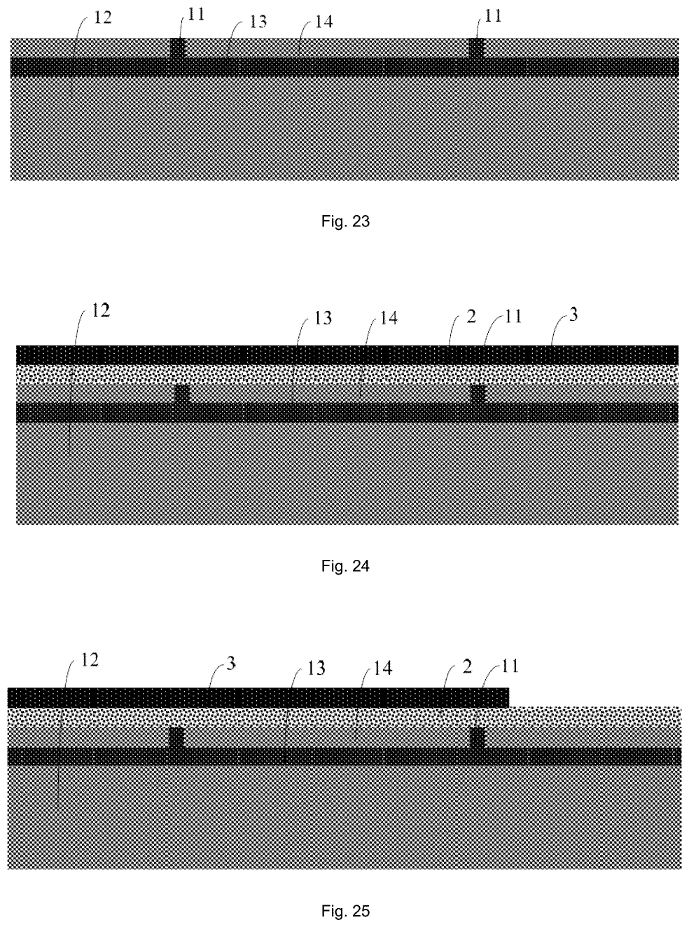

The manner of forming the fifth oxide layer 8 is similar to the manner of forming the fourth oxide layer 7, and the second-time bombardment and subsequently involved bombardment are to bombard the oxide layer by using argon. By means of the method, the protection part 11 without defects, such as the cavity 162, may be formed, the specific structure of the formed protection part 11 may be shown in FIG. 23, and FIG. 23 is another schematic structural diagram of forming the protection part on the substrate.

Specifically, the material of each oxide layer involved in the embodiment may be SiO₂, PSG, TEOS, HDP, etc.

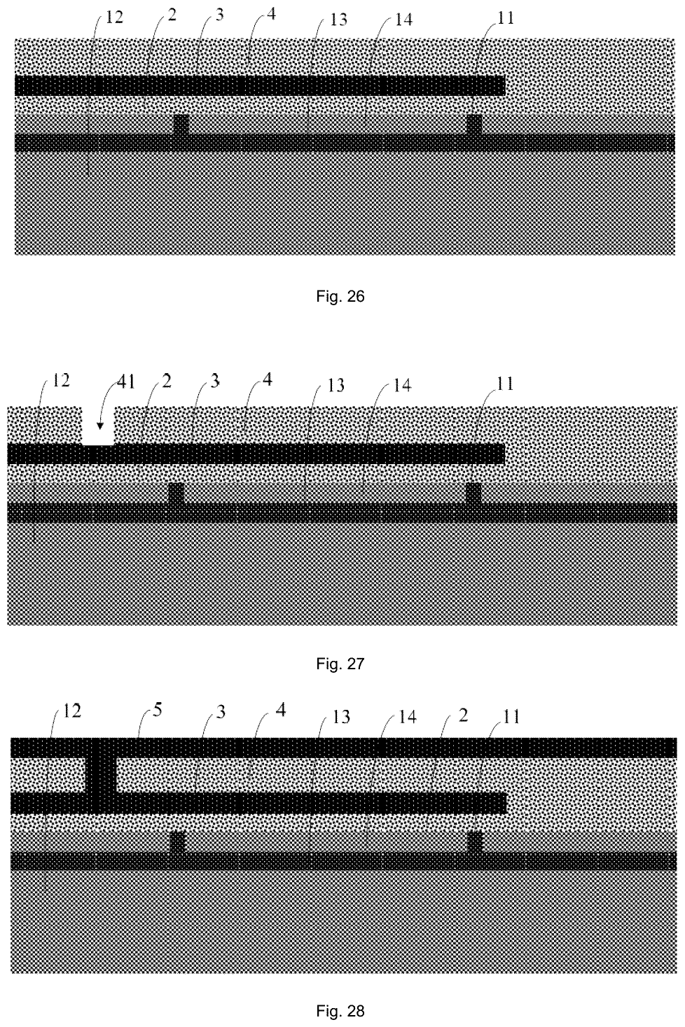

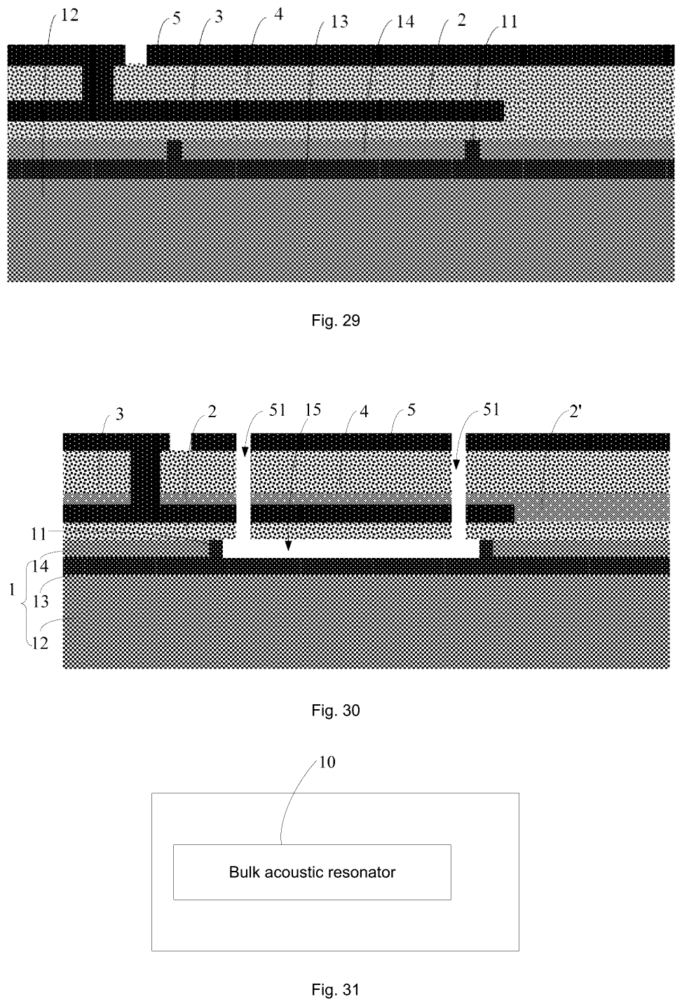

Referring to FIG. 24 to FIG. 29, they are schematic structural diagrams corresponding to specific processes of step S33A′. Step S33c: a seed layer 2, a bottom electrode 3, a piezoelectric layer 4 and a top electrode 5 are sequentially formed on one side of the second semiconductor layer 14 that faces away from the insulating layer 13.

The specific implementation process of the step S33c is the same as or similar to the specific implementation process of the step S4 in the first embodiment, and may achieve the same or similar technical effects, reference may be made to the above description, and thus details are not described herein again.

Referring to FIG. 30, FIG. 30 is a schematic structural diagram of yet another bulk acoustic resonator 10 provided in an embodiment of the present application. In some embodiments, after the step of forming the bottom electrode 3, and before the step of forming the piezoelectric layer 4, another seed layer 2′ may be formed on the side surfaces of the bottom electrode 3 and the seed layer 2 that face away from the second semiconductor layer 14 in advance, and then the piezoelectric layer 4 is formed on one side surface of the seed layer 2′ that faces away from the substrate 1, so as to form a composite piezoelectric layer 4. The composite piezoelectric layer may improve the film quality and inhibit a precipitation problem of the piezoelectric layer 4 due to the doping of rare metal elements. Specifically, the seed layer 2′ may also be formed in an MOCVD manner. In the bulk acoustic resonator 10 shown in FIG. 30, the other portions may have the same arrangement positions as the corresponding portions in the FIG. 1.

In the present embodiment, referring to FIG. 31, FIG. 31 is a schematic structural diagram of a filter provided in an embodiment of the present application. In the present embodiment, a filter is provided, the filter includes the bulk acoustic resonator 10 described above. Since the specific structure of the bulk acoustic resonator 10 and the beneficial effects thereof have been described and illustrated in detail above, details are not described herein again.

It should be noted that, the filter may be constructed by two or more bulk acoustic resonators 10, and since the construction manner of the resonator 10 and the filter is well known to those skilled in the art, details are not described in the present application.

The foregoing descriptions are merely embodiments of the present application, thus are not intended to limit the patent scope of the present application, and any equivalent structures or equivalent process transformations made by using the specification and drawings of the present application, or direct or indirect applications to other related technical fields are all included in the protection scope of the patent of the present application.

What is claimed is:

1. A bulk acoustic resonator, comprising: a substrate, wherein the substrate comprises a first semiconductor layer, an insulating layer and a second semiconductor layer, which are stacked in sequence; the surface of the second semiconductor layer is etched to form a groove, and the groove penetrates through the second semiconductor layer; and a protection part is formed in the groove, and a vertical section of the groove has a smooth contour.

2. The bulk acoustic resonator according to claim 1, wherein in the longitudinal direction of the second semiconductor layer, the width of the vertical section of the groove changes from large to small.

3. The bulk acoustic resonator according to claim 1, wherein the contour of the vertical section of the groove comprises a trapezoid or a rectangle.

4. The bulk acoustic resonator according to claim 1, wherein the notch of the groove has an inclined section, and a inclination angle of the inclined section is not greater than 100.

5. The bulk acoustic resonator according to claim 4, wherein a vertical height of the inclined section is not greater than two thirds of a height of the second semiconductor layer.

6. A preparation method of a bulk acoustic resonator, wherein the method comprises:
providing a substrate, wherein the substrate comprises a first semiconductor layer, an insulating layer and a second semiconductor layer, which are stacked in sequence;
forming an annular groove in the substrate, wherein the annular groove penetrates through the second semiconductor layer;
forming an oxide layer on a surface of the substrate, and filling the annular groove with the oxide layer, so as to form a protection part in the annular groove;
sequentially forming a bottom electrode, a piezoelectric layer and a top electrode on one side surface of the second semiconductor layer that faces away from the insulating layer; and
releasing the second semiconductor layer located in the protection part, so as to form a cavity.

7. The method according to claim 6, wherein,
a vertical section of the annular groove is rectangular; and forming the oxide layer on the surface of the substrate, and filling the annular groove with the oxide layer, so as to form the protection part in the annular groove, comprises:
performing an oxidation treatment on the surface of the second semiconductor layer, so that a portion of the second semiconductor layer is converted into a first oxide layer;
removing the first oxide layer, so that the width of the vertical section of the annular groove changes from large to small in the longitudinal direction of the second semiconductor layer;
forming a second oxide layer on one side surface of the second semiconductor layer that faces away from the first semiconductor layer, and filling the annular groove with the second oxide layer; and
removing the second oxide layer from the side surface of the second semiconductor layer that faces away from the first semiconductor layer, and retaining the second oxide layer in the annular groove, so as to form the protection part.

8. The method according to claim 6, wherein,
in the longitudinal direction of the second semiconductor layer, the width of the vertical section of the annular groove changes from large to small; and
forming the oxide layer on the surface of the substrate, and filling the annular groove with the oxide layer, so as to form the protection part in the annular groove, comprises:
forming a third oxide layer on one side surface of the second semiconductor layer that faces away from the first semiconductor layer, and filling the annular groove with the third oxide layer; and
removing the third oxide layer from the side surface of the second semiconductor layer that faces away from the first semiconductor layer, and retaining the third oxide layer in the annular groove, so as to form the protection part.

9. The method according to claim 6, wherein,
the vertical section of the annular groove is rectangular or tends to be rectangular; and
forming the oxide layer on the surface of the substrate, and filling the annular groove with the oxide layer, so as to form the protection part in the annular groove, comprises:
forming a fourth oxide layer on one side surface of the second semiconductor layer that faces away from the first semiconductor layer, and bombarding the fourth oxide layer for the first time, so as to remove the fourth oxide layer located at the notch of the annular groove, wherein the fourth oxide layer fills a portion of the annular groove;
forming a fifth oxide layer on one side surface of the fourth oxide layer that faces away from the substrate, and bombarding the fifth oxide layer for the second time, so as to remove the fifth oxide layer located at the notch of the annular groove, wherein the fifth oxide layer fills a portion of the annular groove; and by means of analogy in sequence, until the oxide layer completely fills the annular groove, so as to form the protection part.

10. A filter, comprising the bulk acoustic resonator according to claim 1.

11. The filter according to claim 10, wherein in the longitudinal direction of the second semiconductor layer, the width of the vertical section of the groove changes from large to small.

12. The filter according to claim 10, wherein the contour of the vertical section of the groove comprises a trapezoid or a rectangle.

13. The filter according to claim 10, wherein the notch of the groove has an inclined section, and a inclination angle of the inclined section is not greater than 10°.

14. The filter according to claim 13, wherein a vertical height of the inclined section is not greater than two thirds of a height of the second semiconductor layer.
